(19) United States
(12) Patent Application Publication
(10) Pub. No.: US 2014/0137942 A1
(43) Pub. Date: May 22, 2014

(54) Ink composition, thin film solar cell and methods for forming the same

(71) Applicants: Yueh-Chun Liao, Miaoli County (TW); Ching Ting, Miaoli County (TW)

(72) Inventors: Yueh-Chun Liao, Miaoli County (TW); Ching Ting, Miaoli County (TW)

(21) Appl. No.: 13/682,745

(22) Filed: Nov. 21, 2012

(51) Int. Cl. H01L 31/032; H01L 31/18

(52) U.S. Cl. CPC H01L 31/0326; H01L 31/18
USPC 136/260; 136/264; 438/95; 252/512

(57) ABSTRACT

An ink composition, a thin film solar cell and method for forming the thin film solar cell are disclosed. The ink composition includes a solvent system, a source of Cu, a source of Zn, a source of Sn, a source of S and/or Se, and a source of group III element, wherein the ink composition is adapted in forming a I-II-IV-VI thin film solar cell to increase a fill factor of the I-II-IV-VI thin film solar cell.

### BACKGROUND

Photovoltaic devices recently have attracted attention due to energy shortage on Earth. The photovoltaic devices can be boldly classified into crystalline silicon solar cells and thin film solar cells. Crystalline silicon solar cells are the main stream photovoltaic device owing to its mature manufacturing technology and high efficiency. However, crystalline silicon solar cells are still far from common practice because its high material and manufacturing cost. Thin film solar cells are made by forming a light absorbing layer on a non-silicon substrate, such as glass substrate. Glass substrate has no shortage concern and the price thereof is cheaper as comparing with silicon wafers used in crystalline silicon solar cells. Therefore, thin film solar cells are considered as an alternative to crystalline silicon solar cells.

Thin film solar cells can be further classified by material of the light absorbing layers, such as amorphous silicon, Cadmium Telluride (CdTe), Copper indium gallium selenide (CIS or CIGS), Dye-sensitized film (DSC) and other organic films. Among these thin film solar cells, CIGS solar cell has reached small area cell efficiency of 20%, which is comparable with crystalline silicon solar cells. However, CIGS solar cells use rare and expensive elements, i.e., indium and gallium such that they are not well spread in commercial use.

The quaternary chalcogenide semiconductor Cu₂ZnSn(S,Se)₄ (CZTS) is a new photovoltaic material which attracts interests recently due to its use of low cost natural abundant and non-toxic elements. CZTS is a direct band gap material and includes band gap energy in the range of about 1.0-1.5 eV and film absorption coefficient greater than 10⁴ cm⁻¹. The methods of synthesis CZTS absorber film can be classified into vacuum and non-vacuum based methods. The vacuum based methods include deposition of the constitute elements by sputtering or evaporation. The non-vacuum based methods include preparing the CZTS absorber film by spray pyrolysis, electrochemical deposition, coating or printing of precursor solutions. All the methods mentioned above have been utilized in many approaches to improve conversion efficiency of CZTS-based solar cells.

### SUMMARY

The present application provides an ink composition, which includes a solvent system, a source of Cu, a source of Zn, a source of Sn, a source of S and/or Se, and a source of group III element. The ink composition is adapted in forming an I-II-IV-VI thin film solar cell to increase a fill factor of the I-II-IV-VI thin film solar cell.

The present application also provides a thin film solar cell, which includes a substrate, a bottom electrode, an absorber layer having I-II-IV-VI compound semiconductor material and formed on the bottom electrode, a buffer layer formed on the absorber layer, and a top electrode layer formed on the buffer layer. In the thin film solar cell, the absorber layer further includes at least one of aluminum and indium.

The present application further provides a method for forming a thin film solar cell. The method includes steps of forming an absorber layer of I-II-IV-VI compound semiconductor material on a bottom electrode, forming a buffer layer on the absorber layer, and forming a top electrode on the buffer layer. In this method, the step of forming the absorber layer including an addition of group III element to increase a fill factor of the thin film solar cell.

### BRIEF DESCRIPTION OF THE DRAWINGS

The above and other objects, features and other advantages of the present application will be more clearly understood from the following detailed description taken in conjunction with the accompanying drawings, in which:

FIG. 1 is a schematic view of a conventional thin film solar cell.

FIG. 2 is a flow chart of a manufacturing method of the thin film solar cell shown in FIG. 1.

FIG. 3 is a SEM image of a CZTS absorber layer formed by the method of FIG. 2

FIG. 4 is a schematic view of a thin film solar cell according to an embodiment of the present application.

FIG. 5 is a flow chart of a manufacturing method according to an embodiment of the present application.

### DETAIL DESCRIPTION

### Definition

The following definitions are provided to facilitate understanding of certain terms used herein and are not meant to limit the scope of the present disclosure.

“Chalcogen” refers to group VIA elements of periodic table. Preferably, the term “chalcogen” refers to sulfur and selenium.

“CZTS”, in a broad sense, refers to I-II-IV-VI compound semiconductor materials. Generally, the term “CZTS” refers a copper zinc tin sulfide/selenide compound of the formula: e.g. Cuₐ(Zn_{1-b}Sn_{b})(Se_{1-c}S_{c})₂, wherein 0<a<1.5, 0<b<1, 0≦c≦1. Preferably, the term “CZTS” refers a copper zinc tin sulfide/selenide compound of the formula: e.g. Cuₐ(Zn_{1-b}Sn_{b})(Se_{1-c}S_{c})₂, wherein 0<a≦1, 0<b<1, 0≦c≦1. The term “CZTS” further includes copper zinc tin sulfide/selenide compounds with fractional stoichiometries, e.g., Cu_{1.94}Zn_{0.63}Sn_{1.3}S₄. Further, I-II-IV-VI compound semiconductor materials include I-II-IV-IV-VI compound semiconductor materials, such as copper zinc tin germanium sulfide, and I-II-IV-IV-VI-VI compound semiconductor materials such as copper zinc tin germanium sulfide selenide.

“I-II-IV-VI compound semiconductor materials” refers to compound semiconductors composed of group IB element, group IIB element, group IVA element and group VIA element of periodic table, such as CZTS.

“I-II-IV-VI thin film solar cell” refers to a thin film solar cell including an absorber layer having I-II-IV-VI compound semiconductor materials.

“Ink” refers to a solution or slurry containing precursors which can form a semiconductor film. The term “ink” also refers to “precursor solution” or “precursor ink”.

“Metal chalcogenide” refers to a compound composed of metal and group VI element of periodic table. Preferably, the term “metal chalcogenide” refers to binary, ternary and quaternary metal chalcogenide compounds.

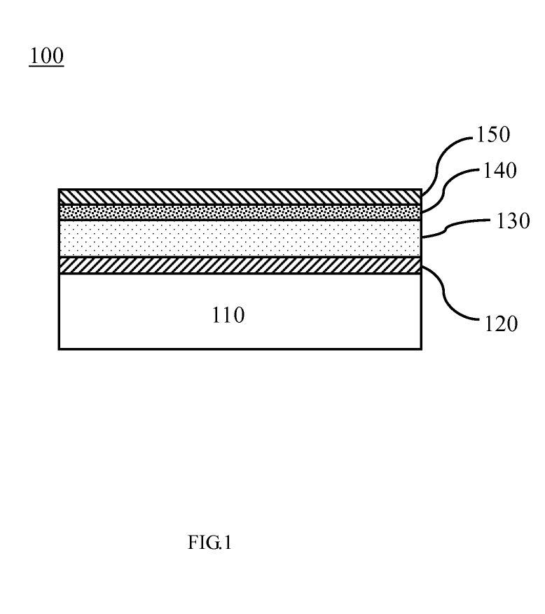

Referring to FIG. 1, it is a schematic view of a conventional thin film solar cell.

As shown in FIG. 1, the thin film solar cell 100 includes a substrate 110, a bottom electrode layer 120, an absorber layer 130, a buffer layer 140 and a top electrode layer 150. The bottom electrode layer 120 is formed on the substrate 110. The absorber layer 130 is formed on the bottom electrode layer 120. The buffer layer 140 is formed on the absorber layer 130. The top electrode layer 150 is formed on the buffer layer 140. Besides, the thin film solar cell 100 can further include metal contacts (not shown in the figure) which are formed on the top electrode layer 150.

The substrate 110 can be rigid or flexible and includes a material selected from a group consisted of glass, metal foil and plastic. For example, the substrate 110 can be a soda-lime glass substrate.

The bottom electrode layer 120 includes a material selected from a group consisted of molybdenum (Mo), tungsten (W), aluminum (Al), indium tin oxide (ITO), boron-doped zinc oxide (B—ZnO), aluminum-doped zinc oxide (Al—ZnO), gallium-doped zinc oxide (Ga—ZnO), and antimony tin oxide (ATO). For example, the bottom electrode layer is a Mo layer.

The absorber layer 130 includes a I-II-IV-VI compound semiconductor material. For example, the absorber layer includes a formula of Cuₐ(Zn_{1-b}Sn_{b})(Se_{1-c}S_{c})₂, wherein 0<a<1.5, 0<b<1, 0≦c≦1.

The method of forming the absorber layer 130 includes coating, electrochemical deposition, or vapor deposition. For example, the coating method includes spin coating, dip coating, doctor blading, curtain coating, slide coating, spraying, slit casting, meniscus coating, screen printing, ink jet printing, pad printing, flexographic printing, and gravure printing. The electrochemical deposition method includes electro-plating. The vapor deposition method includes chemical vapor deposition and physical vapor deposition. For example, the physical vapor deposition method includes electron beam evaporation or radiofrequency magnetron sputtering.

The buffer layer 140 includes an n-type semiconductor layer or a p-type semiconductor layer. When the absorber layer 130 is p-type, the buffer layer 140 is formed of n-type semiconductor material. The buffer layer includes a material selected from a group consisted of cadmium sulfide (CdS), Zn(O,OH,S), indium selenide (In₂Se₃), indium sulfide (In₂S₃), zinc oxide (ZnO), zinc sulfide (ZnS), and zinc magnesium oxide (ZnₓMg₁₋ₓO). Typically, the buffer layer 140 includes CdS formed by chemical bath deposition.

The top electrode layer 150 includes a transparent conductive layer. For example, the top electrode layer 150 includes a material selected from a group consisted of zinc oxide (ZnO), indium tin oxide (ITO), boron-doped zinc oxide (B—ZnO), aluminum-doped zinc oxide (Al—ZnO), gallium-doped zinc oxide (Ga—ZnO), and antimony tin oxide (ATO). In this example, an intrinsic zinc oxide (i-ZnO) film and an indium tin oxide film (ITO) are formed consecutively as the top electrode layer 150 on the buffer layer 140.

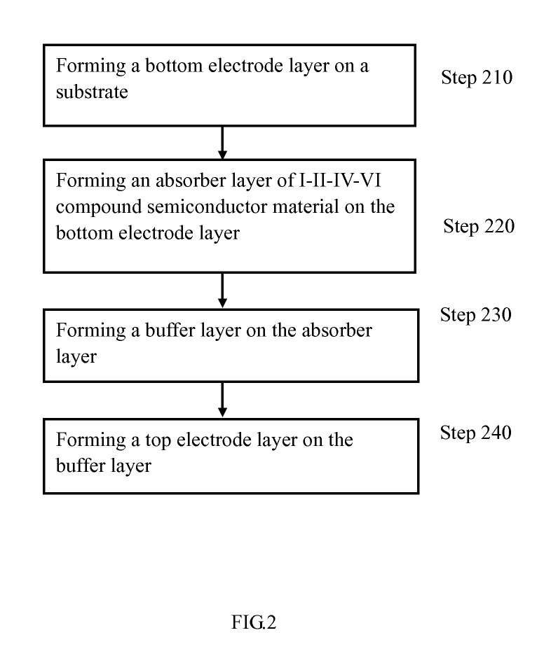

Referring to FIG. 2, it is a flow chart of a manufacturing method of the thin film solar cell of FIG. 1.

In Step 210, a bottom electrode layer 110 is formed on a substrate. For example, the bottom electrode layer 110 is a Mo layer and the substrate is a glass substrate.

In Step 220, an absorber layer 130 of I-II-IV-VI compound semiconductor material is formed on the bottom electrode layer 120. For example, the I-II-IV-VI compound semiconductor material includes a copper zinc tin sulfide/selenide (CZTS) compound of the formula: e.g. Cuₐ(Zn_{1-b}Sn_{b})(Se_{1-c}S_{c})₂, wherein 0<a<1.5, 0<b<1, 0≦c≦1. The method of forming a CZTS layer includes coating, electrochemical deposition, or vapor deposition. For example, the coating method, i.e., a solution process, generally includes coating a CZTS precursor ink to form a liquid layer and then drying and annealing the liquid layer to form the CZTS layer.

The CZTS precursor ink includes a solvent system, a source of Cu, a source of Zn, a source of Sn and a source of S and/or Se. The solvent system includes polar solvents or non-polar solvents. The source of Cu, a source of Zn and a source of Sn include, i.e., come from, at least one metal source selected from the group consisted of metal ions, metal complex ions, metal chalcogenides and metal powder.

For example, the CZTS precursor ink includes an aqueous solution of metal chalcogenide nanoparticles and at least one of metal ions and metal complex ions which include metals of copper, zinc and tin.

Other polar solvents include, for example, hydrazine. The CZTS precursor ink can include a hydrazine solution and metal ions and/or metal powder of copper, zinc and tin which are dispersed in the hydrazine solution. In addition to the precursor ink having polar solvents, the precursor ink can utilize non-polar solvents, such as, chlorobenzene.

In step 230, a buffer layer 140 is formed on the absorber layer 130. The buffer layer 140, for example, is a CdS layer formed by chemical bath deposition.

In step 240, a top electrode layer 150 is formed on the buffer layer. The top electrode layer 240, for example, is an ITO layer.

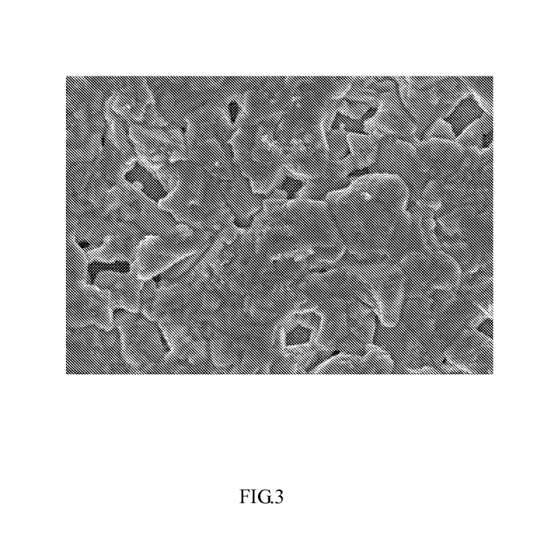

Referring to FIG. 3, it is a SEM image of a CZTS absorber layer formed by the method of FIG. 2. As shown in the FIG. 3, there are some cracks and voids formed on the surface of the CZTS absorber layer. Besides, there is also a need to improve electric characteristic of the thin film solar cell of FIG. 1.

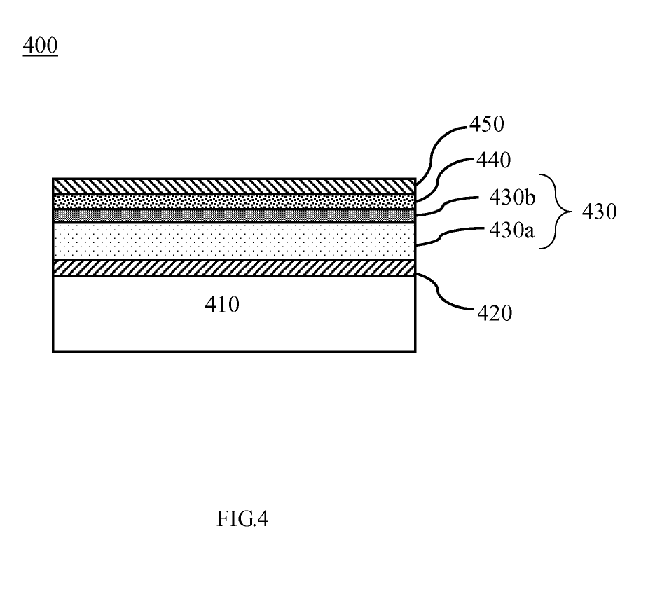

Referring to FIG. 4, it is a schematic view of a thin film solar cell according to an embodiment of the present application. As shown in FIG. 4, the thin film solar cell 400 includes a substrate 410, a bottom electrode layer 420, an absorber layer 430, a buffer layer 440 and a top electrode layer 450. In the thin film solar cell 400, the absorber layer 430 includes a main portion 430a and a modulation portion 430b.

The material of the substrate 410, the bottom electrode layer 420, the buffer layer 440 and the top electrode layer 450 are similar to the thin film solar cell 100 mentioned above. Therefore, the detail description of these layers is omitted here for clarity.

The absorber layer 430 includes a main portion 430a and a modulation portion 430b, wherein the modulation portion 430b is formed on an upper interface region of the absorber layer 430. That is, in this embodiment, the modulation portion 430b is formed above the main portion 430a. The main portion 430a of the absorber layer 430 includes a material selected from the I-II-IV-VI compound semiconductor material. For example, the main portion 430a includes a copper zinc tin sulfide/selenide (CZTS) compound of the formula: e.g. Cuₐ(Zn_{1-b}Sn_{b})(Se_{1-c}S_{c})₂, wherein 0<a<1.5, 0<b<1, 0≦c≦1. The modulation portion 430b of the absorber layer 430 includes a major composition which is substantially the same with the main portion 430a and further includes a source of group IIIA element of periodic table. For example, the modulation portion 430a includes a CZTS material of the formula: e.g. Cuₐ(Zn_{1-b}Sn_{b})(Se_{1-c}S_{c})₂, wherein 0<a<1.5, 0<b<1, 0≦c≦1, and further includes aluminum (Al). The modulation portion 430b is capable of improving film quality and electric characteristic of the absorber layer 430, such as improving film uniformity or increasing fill factor.

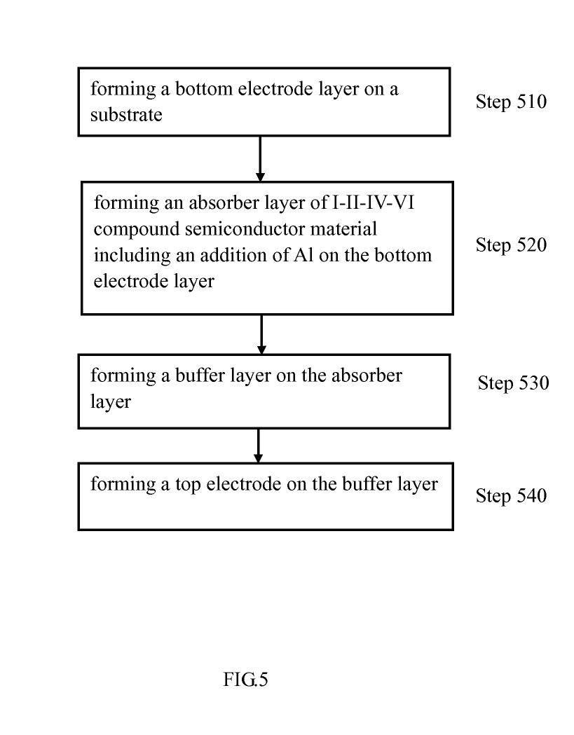

Hereinafter, a manufacturing method of the thin film solar cell 400 will be described with reference to FIG. 5. FIG. 5 is a flow chart of a manufacturing method according to an embodiment of the present application.

In step 510, the bottom electrode layer 420 is formed on the substrate 410.

In step 520, the absorber layer 430 of I-II-IV-VI compound semiconductor material including an addition of Al is formed on the bottom electrode layer 420. The steps of forming the absorber layer 430 include forming the main portion 430a on the bottom electrode layer 410 first, and then forming the modulation portion 430b on the main portion 430a. The methods of forming the main portion 430a and the modulation portion 430b are similar to the methods for forming a I-II-IV-VI compound semiconductor material layer, such as coating, electrochemical deposition, or vapor deposition.

In this embodiment, a coating method is described for example. First, a first precursor ink of CZTS having a formula of Cuₐ(Zn_{1-b}Sn_{b})(Se_{1-c}S_{c})₂, wherein 0<a<1.5, 0<b<1, 0≦c≦1, is coated and dried on the bottom electrode layer 410. The step can be repeated for about 3 to 6 times to form a film. Then, a second precursor ink having a composition substantially the same with the first precursor ink and an addition of Al is coated and dried on the film formed by the first precursor ink. The step also can be repeated for several times so as to form a precursor film on the bottom electrode layer. Then, the sample is annealed to form the absorber layer 430 which includes the major portion 430a formed by the first precursor ink and the modulation portion 430b formed by the second precursor ink.

Next, in step 530, a buffer layer 440 is formed on the absorber layer. Then, in step 540, a top electrode layer 450 is formed on the buffer layer 440.

In addition to the coating method, other methods, such as vapor deposition or electro-plating, also can be used to form the absorber layer 430. In vapor deposition or electroplating method, a two-step process can be adapted to form the absorber layer 430. For example, the process includes first forming the main portion 430a having a formula of Cuₐ(Zn_{1-b}Sn_{b})(Se_{1-c}S_{c})₂, wherein 0<a<1.5, 0<b<1, 0≦c≦1, by vapor deposition and then forming the modulation portion having a composition substantially the same with the main portion and an addition of Al by vapor deposition.

Even though in this embodiment, a modulation portion 430b is formed in an upper interface region of the absorber layer 430. However, in other embodiments, the modulation portion 430b also can be formed in a lower interface region of the absorber layer 430. That is, the modulation portion 430b can be formed under the main portion 430a in the absorber layer 430. Moreover, the modulation portion 430b can be formed in both of the lower interface region and the upper interface region of the absorber layer 430.

Hereinafter, several examples of the present application will be described in detail.

### Preparation of Precursor Ink

According to an embodiment of the present application, a precursor ink of forming a CZTS absorber layer includes a solvent system and a source of copper (Cu), a source of zinc (Zn), a source of tin (Sn), a source of chalcogen (sulfur (S) or selenium (Se)) and a source of group III element, such as aluminum (Al), or indium (In). In the following examples, the solvent system includes an aqueous solution. The source of copper (Cu), a source of zinc (Zn), a source of tin (Sn), and a source of group IIIA element come from at least one metal source selected from the group consisted of metal ions, metal complex ions, metal chalcogenides and metal powder. Besides, thiourea solution and/or ammonium sulfide solution are used as the source of chalcogen.

### (1) the First Precursor Ink (CZTS)

Preparation of a source of Sn: 1.07 mmol of tin chloride (SnCl₂) was dissolved in 1.5 ml of H₂O and stirring for 2 minutes to form an aqueous solution (A1).

Preparation of a source of Zn: 1.31 mmol of zinc nitrate (Zn(NO₃)₂) was dissolved in 1 ml of H₂O to form an aqueous solution (B1).

Preparation of a source of Cu: 1.70 mmol of copper nitrate (Cu(NO₃)₂) was dissolved in 1.0 ml of H₂O to form an aqueous solution (C1).

Preparation of a source of chalcogen: 3.00 mmol of thiourea was dissolved in 3 ml of H₂O to form an aqueous solution (D1).

The aqueous solution (A1) and the aqueous solution (D1) were mixed and stirred for 2 minutes at 90° C. to form a solution (E1).

The aqueous solution (C1) was mixed with the solution (E1) and stirred for 2 minutes at 90° C. to form a solution (F1).

The aqueous solution (B1) was mixed with the solution (F1) and stirred for 10 minutes at 90° C. to form a solution (G1).

Formation of the ink: 1.5 mL of 40˜44% ammonium sulfide aqueous solution was added into the solution (G1) at room temperature and then stirred overnight or sonication for 30 minutes to form an ink.

### (2) the Second Precursor Ink (Al:CZTS)

Preparation of a source of Sn: 1.07 mmol of tin chloride (SnCl₂) was dissolved in 1.5 ml of H₂O and stirring for 2 minutes to form an aqueous solution (A2).

Preparation of a source of Zn: 1.31 mmol of zinc nitrate (Zn(NO₃)₂) was dissolved in 1 ml of H₂O to form an aqueous solution (B2).

Preparation of a source of Cu: 1.70 mmol of Cu(NO₃)₂ was dissolved in 1.0 ml of H₂O to form an aqueous solution (C2).

Preparation of a source of chalcogen: 3.00 mmol of thiourea was dissolved in 3 ml of H₂O to form an aqueous solution (D2).

Preparation of a source of Al: 0.05 mmol of aluminum nitrate (Al(NO₃)₃) was dissolved in 0.2 ml of H₂O to form an aqueous solution (E2).

The aqueous solution (A2) and the aqueous solution (D2) were mixed and stirred for 2 minutes at 90° C. to form a solution (F2).

The aqueous solution (C2) was mixed with the solution (F2) and stirred for 2 minutes at 90° C. to form a solution (G2).

The aqueous solution (B2) was mixed with the solution (G2) and stirred for 2 minutes at 90° C. to form a solution (H2).

The aqueous solution (E2) was mixed with the solution (H2) and stirred for 10 minutes at 90° C. to form a solution (I2).

Formation of the chalcogenide ink: 1.8 mL of 40˜44% ammonium sulfide aqueous solution was added into the solution (I2) at room temperature and then sonication for 30 minutes to form a mixture solution (J2).

Formation of the ink: 0.2 mL of 1 wt % sodium hydroxide aqueous solution was added into the mixture solution (J2) at room temperature and then sonication for 30 minutes or stirred overnight to form an ink (K2).

### (3) the Third Precursor Ink (In:CZTS)

Preparation of a source of Sn: 1.07 mmol of tin chloride (SnCl₂) was dissolved in 1.5 ml of H₂O and stirring for 2 minutes to form an aqueous solution (A3).

Preparation of a source of Zn: 1.31 mmol of zinc nitrate (Zn(NO₃)₂) was dissolved in 1 ml of H₂O to form an aqueous solution (B3).

Preparation of a source of Cu: 1.70 mmol of copper nitrate (Cu(NO₃)₂) was dissolved in 1.0 ml of H₂O to form an aqueous solution (C3).

Preparation of a source of chalcogen: 3.00 mmol of thiourea was dissolved in 3 ml of H₂O to form an aqueous solution (D3).

Preparation of a source of In: 0.05 mmol of Indium chloride (InCl₂) was dissolved in 0.2 ml of H₂O to form an aqueous solution (E3).

The aqueous solution (A3) and the aqueous solution (D3) were mixed and stirred for 2 minutes at 90° C. to form a solution (F3).

The aqueous solution (C3) was mixed with the solution (F3) and stirred for 2 minutes at 90° C. to form a solution (G3).

The aqueous solution (B3) was mixed with the solution (G3) and stirred for 2 minutes at 90° C. to form a solution (H3).

The aqueous solution (E3) was mixed with the solution (H3) and stirred for 10 minutes at 90° C. to form a solution (I3).

Formation of the chalcogenide ink: 1.8 mL of 40˜44% ammonium sulfide aqueous solution was added into the solution (I3) at room temperature and then sonication for 30 minutes to form a mixture solution (J3).

Formation of the ink: 0.2 mL of 1 wt % sodium hydroxide aqueous solution was added into the mixture solution (J3) at room temperature and then sonication for 30 minutes or stirred overnight to form an ink (K3).

### Formation an Absorber Layer Including Al

### Comparative Example 1

### Formation of an Absorber Layer without a Modulation Portion

The first precursor ink was deposited on a 2×2 inch Mo-coated soda lime glass by spin-coating in a nitrogen-filled glovebox. For a 2×2 inch substrate, an amount of about 360 μL of the first precursor ink was dropped onto the substrate, followed by a spin-coating recipe of 500 rpm for 9 seconds and 600 rpm for 1 second to form a liquid layer on the substrate. Then the liquid layer was dried at 215° C. for 2 minutes, followed by baking at 435° C. for 2 minutes, and then cooled to room temperature. This procedure was repeated 6 times to form a precursor film on the substrate. Then, the precursor film was heated at 600˜650° C. for 14 minutes in the presence of 80 mg of Se vapor to form an absorber layer. Then the absorber layer was cooled down to room temperature.

### Example 1

### Formation of an Absorber Layer with a Modulation Portion (Al:CZTS) in the Upper Interface Region

The first precursor ink (CZTS) was deposited on a 2×2 inch Mo-coated soda lime glass (substrate) by spin-coating in a nitrogen-filled glovebox. For a 2×2 inch substrate, an amount of about 360 μL of the first precursor ink was dropped onto the substrate, followed by a spin-coating method to form a first liquid layer on the substrate. The spin-coating recipe included a first spin cycle of 550 rpm for 9 seconds and a second spin cycle of 680 rpm for 1 second. Then the first liquid layer was dried at 215° C. for 2 minutes, followed by baking at 435° C. for 2 minutes, and then cooled to room temperature. This procedure was repeated 6 times to form a film on the substrate. Thereafter, an amount of about 360 μL of the second precursor ink (Al:CZTS) was dropped onto the film formed by the first precursor ink, followed by a spin-coating recipe of 500 rpm for 9 seconds and 600 rpm for 1 second to form a second liquid layer. The second liquid layer was dried at 215° C. for 2 minutes, followed by baking at 435° C. for 2 minutes, and then cooled to room temperature. The procedure was repeated 2 times.

Following the above steps, a precursor film was formed on the substrate Then, the sample was heated at 600˜650° C. for 14 minutes in the presence of 80 mg of selenium (Se) vapor to convert the precursor film to absorber layer. The absorber layer was cooled down to room temperature.

### Example 2

### Formation of the Absorber Layer with Modulation Portions (Al:CZTS) in Both of the Upper Interface Region and the Lower Interface Region

The second precursor ink (Al:CZTS) was deposited on a 2×2 inch Mo-coated soda lime glass by spin-coating in a nitrogen-filled glovebox. For a 2×2 inch substrate, an amount of about 360 μL of the second precursor ink was dropped on the substrate, followed by a spin-coating recipe of 500 rpm for 9 seconds and 600 rpm for 1 second to form a first liquid layer (Al:CZTS). Then, the first liquid layer was dried at 215° C. for 2 minutes, followed by annealing at 435° C. for 2 minutes, and then cooled to room temperature. This procedure was repeated 2 times to form a film on the bottom electrode. Thereafter, an amount of about 360 μL of the first precursor ink (CZTS) was dropped onto the film formed by the second precursor ink, followed by a spin-coating recipe of 550 rpm for 9 seconds, 680 rpm for 1 second to form a second liquid layer. The second liquid layer was dried at 215° C. for 2 minutes, followed by baking at 435° C. for 2 minutes, and then cooled to room temperature. This procedure was repeated 4 times. Then, an amount of about 360 μL of the second precursor ink (Al:CZTS) was dropped onto a resulted film formed by the above steps, and then followed by a spin-coating recipe of 500 rpm for 9 seconds and 600 rpm for 1 second to form a third liquid layer. Then, the third liquid layer was dried at 215° C. for 2 minutes, followed by baking at 435° C. for 2 minutes, and then cooled to room temperature. This procedure was repeated 2 times.

Following the above steps, a precursor film is formed on the substrate. Then, the precursor film was heated at 600˜650° C. for 14 minutes in the presence of 80 mg of Se vapor to form an absorber layer. Then the absorber layer was cooled down to room temperature.

### Example 3

### Formation of the Absorber Layer with a Modulation Portion (Al:CZTS) in the Lower Interface Region

The second precursor ink (Al:CZTS) was deposited on a 2×2 inch Mo-coated soda lime glass by spin-coating in a nitrogen-filled glovebox. For a 2×2 inch substrate, an amount of 360 μL of the second precursor ink was dropped onto the substrate, followed by a spin-coating recipe of 500 rpm for 9 seconds and 600 rpm for 1 second to form a first liquid layer. Then, the first liquid layer was dried at 215° C. for 2 minutes, followed by baking at 435° C. for 2 minutes, and then cooled to room temperature. This procedure was repeated 2 times to form a film (Al:CZTS) on the substrate. Thereafter, an amount of about 360 μL of the first precursor ink (CZTS) was dropped onto the film formed by the second precursor ink, followed by a spin-coating recipe of 550 rpm for 9 seconds, 680 rpm for 1 second to form a second liquid layer. The second liquid layer was dried at 215° C. for 2 minutes, followed by baking at 435° C. for 2 minutes, and then cooled to room temperature. This procedure was repeated 6 times.

Following the above steps, a precursor film was formed on the bottom electrode. Then, the precursor film was heated at 600˜650° C. for 14 minutes. The absorber layer was cooled down to room temperature.

### Evaluation of the Thin Film Solar Cells

The open-circuit voltage (V_{oc}), short-circuit current (J_{sc}), fill factor (F.F.), conversion efficiency (η), series resistance (Rₛ) and shunt resistance (Rₛₕ) of the thin film solar cells having the absorber layers of Example 1, Example 2, Example 3 and Comparative Example respectively were determined and listed in Table 1.

TABLE 1

| | V_{oc} | J_{sc} | FF | Efficiency | Rₛ | Rₛₕ |
|---|---|---|---|---|---|---|
| | (mV) | (mA/cm²) | (%) | (%) | (Ohm) | (Ohm) |
| Comparative | 481 | 31.8 | 63.3 | 9.7 | 5.2 | 467 |
| Example 1 | | | | | | |
| Example 1 | 483 | 30.1 | 65.4 | 9.5 | 5 | 683 |
| Example 2 | 477 | 29.6 | 66.4 | 9.4 | 4.4 | 565 |
| Example 3 | 493 | 30.6 | 65.9 | 10 | 5.2 | 1095 |

As shown in Table 1, the fill factors of Example 1 to Example 3 are higher than that of the Comparative example. Besides, the series resistances of Example 1 and Example 2 are lower than that of the Comparative example. Therefore, it was shown that an addition of Al in the absorber layer is capable of improving electric characteristic of the I-II-IV-VI compound semiconductor-based thin film solar cell.

### Formation an Absorber Layer Including al

### Comparative Example 2

### Formation of an Absorber Layer without a Modulation Portion

The first precursor ink was deposited on a 2×2 inch Mo-coated soda lime glass by spin-coating in a nitrogen-filled glovebox. For a 2×2 inch substrate, an amount of about 360 μL of the first precursor ink was dropped onto the substrate and followed by a spin-coating recipe of 500 rpm for 9 seconds and 600 rpm for 1 second to form a liquid layer on the substrate. Then the liquid layer was dried at 215° C. for 2 minutes, followed by baking at 435° C. for 2 minutes, and then cooled to room temperature. This procedure was repeated 6 times to form a precursor film on the substrate. Then, the precursor film was heated at 600˜650° C. for 14 minutes in the presence of 80 mg of Se vapor to form an absorber layer. Then the absorber layer was cooled down to room temperature.

### Example 4

### Formation of an Absorber Layer with a Modulation Portion (In:CZTS) in the Upper Interface Region

The first precursor ink (CZTS) was deposited on a 2×2 inch Mo-coated soda lime glass (substrate) by spin-coating in a nitrogen-filled glovebox. For a 2×2 inch substrate, 360 μL of the first precursor ink was dropped on the substrate, followed by a spin-coating method to form a first liquid layer on the substrate. The spin-coating recipe included a first spin cycle of 550 rpm for 9 seconds and a second spin cycle of 680 rpm for 1 second. Then, the first liquid layer was dried at 215° C. for 2 minutes, followed by baking at 435° C. for 2 minutes, and then cooled to room temperature. This procedure was repeated 6 times to form a film on the substrate. Thereafter, an amount of 360 μL of the third precursor ink (In:CZTS) was dropped on the film formed by the first precursor ink, followed by a spin-coating recipe of 500 rpm for 9 seconds and 600 rpm for 1 second to form a second liquid layer. The second liquid layer was annealed at 215° C. for 2 minutes, followed by annealing at 435° C. for 2 minutes, and then cooled to room temperature. This procedure was repeated for 2 times to form an In:CZTS film.

Following the above steps, a precursor film was formed on the substrate. Then, the sample was heated at 600˜650° C. for 14 minutes in the presence of 80 mg of selenium vapor (Se) to convert the precursor film to absorber layer. The absorber layer was cooled down to room temperature.

### Example 5

### Formation of the Absorber Layer with a Modulation Portion (In:CZTS) in the Lower Interface Region

The third precursor ink was deposited on a 2×2 inch Mo-coated soda lime glass (substrate) by spin-coating in a nitrogen-filled glovebox. For a 2×2 inch substrate, 360 μL of the third precursor ink was dropped on the substrate, followed by a spin-coating recipe of 500 rpm for 9 seconds and 600 rpm for 1 second to form a first liquid layer. Then, the first liquid layer was dried at 215° C. for 2 minutes, followed by baking at 435° C. for 2 minutes, and then cooled to room temperature. This procedure was repeated for 2 times to form a film (In:CZTS) on the substrate. Thereafter, an amount of 360 μL of the first precursor ink was dropped on the film, followed by a spin-coating recipe of 550 rpm for 9 seconds, 680 rpm for 1 second to form a second liquid layer. The second liquid layer was dried at 215° C. for 2 minutes, followed by baking at 435° C. for 2 minutes, and then cooled to room temperature. This procedure was repeated 6 times.

Following the above steps, a precursor film was formed on the bottom electrode. Then, the completed precursor film was heated at 600˜650° C. for 14 minutes in the presence of 80 mg of selenium vapor (Se) to convert the precursor film to absorber layer. Then the film was cooled down to room temperature.

### Evaluation of the Thin Film Solar Cells

The open-circuit voltage (V_{oc}), short-circuit current (J_{sc}), fill factor (F.F.), conversion efficiency (η), series resistance (Rₛ) and shunt resistance (Rₛₕ) of the thin film solar cells having the absorber layers of Comparative Example 2, Example 4 and Example 5 were determined and listed in Table 2, respectively.

TABLE 2

| | V_{oc} | J_{sc} | FF | Efficiency | Rₛ | Rₛₕ |
|---|---|---|---|---|---|---|
| | (mV) | (mA/cm²) | (%) | (%) | (Ohm) | (Ohm) |
| Comparative | 402 | 27.2 | 46.7 | 5.1 | 8.1 | 130 |
| Example 2 | | | | | | |
| Example 4 | 400 | 26.6 | 47.7 | 5.1 | 7.1 | 106 |
| Example 5 | 415 | 25.4 | 52.3 | 5.5 | 8.1 | 258 |

As shown in Table 2, the fill factors of Example 4 and Example 5 are higher than that of Comparative Example 2. Thus, it was shown that an addition of In in the absorber layer is capable of improving electric characteristic of the I-II-IV-VI compound semiconductor-based thin film solar cell.

Though in Example 1 to Example 5, the modulation portion were formed in the upper interface region and/or the lower interface region of the absorber layer, the modulation portion also can be formed in a middle region and/or other position of the absorber layer.

Besides, it shall be noted here that even though a source of Al or In is added into the modulation portion, other group III elements of periodic table, which also can improve an electric characteristic, such as fill factor, of a thin film solar cell also can be used.

What is claimed is:

1. An ink composition, comprising:
a solvent system; and
a source of Cu, a source of Zn, a source of Sn, a source of S and/or Se, and a source of group III element; wherein the ink composition is adapted in forming a I-II-IV-VI thin film solar cell to increase a fill factor of the I-II-IV-VI thin film solar cell.

2. The ink composition according to claim 1, wherein the source of group III element includes at least one selected from the group consisted of aluminum and indium.

3. The ink composition according to claim 1, wherein the solvent system includes polar solvents.

4. The ink composition according to claim 1, wherein the polar solvents include at least one selected from the group consisted of water, methanol, ethanol, isopropyl alcohol, dimethyl sulfoxide (DMSO), amines and hydrazine.

5. The ink composition according to claim 3, wherein the source of Cu, the source of Zn, the source of Sn and the source of group III element include at least one selected from the group consisted of metal ions, metal complex ions, metal chalcogenides and metal powder.

6. The ink composition according to claim 1, wherein the I-II-IV-VI thin film solar cell includes an absorber layer substantially having a formula of Cuₐ(Zn_{1-b}Sn_{b})(Se_{1-c}S_{c})₂, wherein 0<a<1.5, 0<b<1, 0≦c≦1.

7. A thin film solar cell, comprising:
a substrate;
a bottom electrode;
an absorber layer having I-II-IV-VI compound semiconductor material and formed on the bottom electrode;
a buffer layer, formed on the absorber layer; and
a top electrode layer, formed on the buffer layer; wherein the absorber layer further includes at least one of aluminum and indium.

8. The thin film solar cell according to claim 7, wherein the I-II-IV-VI compound semiconductor material includes a formula of Cuₐ(Zn_{1-b}Sn_{b})(Se_{1-c}S_{c})₂, wherein 0<a<1.5, 0<b<1, 0≦c≦1.

9. The thin film solar cell according to claim 7, wherein the at least one of aluminum and indium is positioned in an upper interface region and/or a lower interface region of the absorber layer.

10. The thin film solar cell according to claim 7, wherein the buffer layer includes a material selected from a group consisted of cadmium sulfide (CdS), Zn(O,OH,S), indium selenide (In₂Se₃), indium sulfide (In₂S₃), zinc oxide (ZnO), zinc sulfide (ZnS), and zinc magnesium oxide (ZnₓMg₁₋ₓO).

11. A method for forming a thin film solar cell, comprising:
forming an absorber layer of I-II-IV-VI compound semiconductor material on a bottom electrode;
forming a buffer layer on the absorber layer; and
forming a top electrode on the buffer layer, wherein the step of forming the absorber layer including an addition of group III element to increase a fill factor of the thin film solar cell.

12. The method according to claim 11, wherein the step of forming the addition of group III element includes using at least one of aluminum and indium.

13. The method according to claim 11, wherein the step of forming the absorber layer includes at least one selected from the group consisted of coating, electrochemical deposition, or vapor deposition.

14. The method according to claim 11, wherein the step of forming the absorber layer including:
forming a main portion of the I-II-IV-VI compound semiconductor material;
forming a modulation portion having the I-II-IV-VI compound semiconductor material and the addition of group III element; and
annealing the main portion and the modulation portion.

15. The method according to claim 14, wherein the step of forming the modulation portion is performed before and/or after the step of forming the main portion.

16. The method according to claim 14, wherein the steps of forming the main portion and/or the modulation portion include a coating method.

17. The method according to claim 16, wherein the step of forming the absorber layer includes using a first ink for forming the main portion and using a second ink for forming the modulation portion.

18. The method according to claim 16, wherein the coating method includes wet-coating, printing, spin coating, dip coating, doctor blading, curtain coating, slide coating, spraying, slit casting, meniscus coating, screen printing, ink jet printing, pad printing, flexographic printing, and gravure printing.

19. The method according to claim 14, wherein the step of forming the modulation portion includes using an ink composition including:
a solvent system; and a source of Cu, a source of Zn, a source of Sn, a source of S and/or Se, and a source of group III element.
